(19) United States
(12) Patent Application Publication
(10) Pub. No.: US 2015/0355286 A1
(43) Pub. Date: Dec. 10, 2015

(54) SYSTEM FOR ESTIMATING FAILURE IN CELL MODULE

(71) Applicant: SANYO ELECTRIC CO., LTD., Daito-shi, Osaka (JP)

(72) Inventors: NORIHARU KOBAYASHI, Hyogo (JP); MUTSUHIKO TAKEDA, Osaka (JP); NAOHISA MORIMOTO, Osaka (JP)

(21) Appl. No.: 14/761,021

(22) PCT Filed: Jan. 16, 2014
(86) PCT No.: PCT/JP2014/000179

§ 371 Date: Jul. 15, 2015

(30) Foreign Application Priority Data
Jan. 22, 2013 (JP) 2013-009553

(51) Int. Cl. G01R 31/36; H01M 10/48

(52) U.S. Cl. CPC G01R 31/3658; G01R 31/3624; G01R 31/3648; H01M 10/482

(57) ABSTRACT

In failure estimating system for a battery module, failure estimating device includes: charge state calculating unit for calculating the charge state of battery module; ΔSOC calculating unit for calculating ΔSOC as the amount of variation of the charge state from the initial charge state of battery module; ΔV integrated value calculating unit for calculating ΔV as the difference between a maximum inter-terminal voltage value and a minimum inter-terminal voltage value among a plurality of battery blocks and calculating a ΔV integrated value by sequentially integrating the calculated ΔV; and number-of-failed-cells estimating unit for estimating, with reference to association file, the number of failed cells that corresponds to the calculated ΔSOC and ΔV integrated value. Association file is stored in storage unit, and associates the relationship between ΔSOC and ΔV integrated value with the number of failed cells.

### TECHNICAL FIELD

The present invention relates to a failure estimating system for a battery module for estimating the number of failed cells in a battery module that is formed by interconnecting a plurality of battery blocks each of which includes a plurality of interconnected cells.

### BACKGROUND ART

Patent Literature 1 discloses a battery module formed by electrically interconnecting two battery blocks in series. Each battery block is a connection body where a plurality of lithium ion cells are electrically interconnected in series.

### CITATION LIST

### Patent Literature

PTL 1: Unexamined Japanese Patent Publication No. 2012-221844

### SUMMARY OF THE INVENTION

The purpose of the present invention is to provide a failure estimating system for estimating the number of failed cells in a battery module that is formed by interconnecting a plurality of battery blocks each of which includes a plurality of interconnected cells.

A failure estimating system for a battery module of the present invention includes the following components:

a battery module formed by interconnecting, in series, a plurality of battery blocks each of which includes a plurality of cells interconnected in parallel;

a current detecting unit for detecting the current output from or input to the battery module when the battery module is connected to a discharge load or charge power source;

a plurality of voltage detecting units for detecting the inter-terminal voltage of each of the battery blocks; and

a failure estimating device for estimating and outputting the number of failed cells that do not contribute to charge and discharge, of the plurality of cells constituting each of the battery blocks.

The failure estimating device includes the following components:

a charge state calculating unit for calculating the charge state of the battery module by integrating the current detected by the current detecting unit;

a ΔSOC (state of charge) calculating unit that, at each predetermined detection cycle between the initial time and final time of a predetermined failure estimation period, calculates charge state variation ΔSOC—the amount of variation of the charge state from the initial charge state of the battery module—on the basis of the calculated value by the charge state calculating unit;

a ΔV integrated value calculating unit for calculating inter-block maximum voltage difference ΔV—the difference between a maximum inter-terminal voltage value and a minimum inter-terminal voltage value among the battery blocks—at each detection cycle on the basis of the detected values by the voltage detecting units, and calculating a ΔV integrated value, which is the integrated value at the final time, by sequentially integrating the calculated ΔV from the initial time of the failure estimation period;

a storage unit for storing, as an association file, the relationship between the ΔSOC and the ΔV integrated value in association with the number of failed cells; and

an estimating unit for estimating, with reference to the association file, the number of failed cells that corresponds to the ΔSOC and the ΔV integrated value at the final time of the failure estimation period.

### BRIEF DESCRIPTION OF DRAWINGS

FIG. 1 is a block diagram of a failure estimating system for a battery module in an example in accordance with an exemplary embodiment of the present invention.

FIG. 2 is a block diagram of a battery block in the failure estimating system for the battery module in the example in accordance with the exemplary embodiment of the present invention.

FIG. 3 is a diagram illustrating an estimation principle of the failure estimating system for the battery module in the example in accordance with the exemplary embodiment of the present invention.

FIG. 4 is a model diagram of a cell in the failure estimating system for the battery module in the example in accordance with the exemplary embodiment of the present invention.

FIG. 5 is a diagram showing an example of an association file in the failure estimating system for the battery module in the example in accordance with the exemplary embodiment of the present invention.

FIG. 6 is a flowchart showing the procedure of failure estimation of the battery module in the example in accordance with the exemplary embodiment of the present invention.

FIG. 7 is a diagram showing a charge/discharge pattern used for the failure estimation of the battery module in the example in accordance with the exemplary embodiment of the present invention.

FIG. 8 is a diagram showing an example of calculation data for the failure estimation of the battery module in the example in accordance with the exemplary embodiment of the present invention.

FIG. 9 is a diagram showing the relationship between ΔSOC and ΔV integrated value in FIG. 8.

### DESCRIPTION OF EMBODIMENTS

An example of an exemplary embodiment of the present invention is described hereinafter in detail with reference to the accompanying drawings. The number of cells, the number of battery blocks, the inter-terminal voltage value of each battery block, the ΔSOC value, and the ΔV integrated value that are described later are examples for description, and can be appropriately modified in accordance with the contents of an estimating object of a failure estimating system for a battery module. Hereinafter, corresponding components in all drawings are denoted with the same reference marks, and the duplication of the descriptions is omitted.

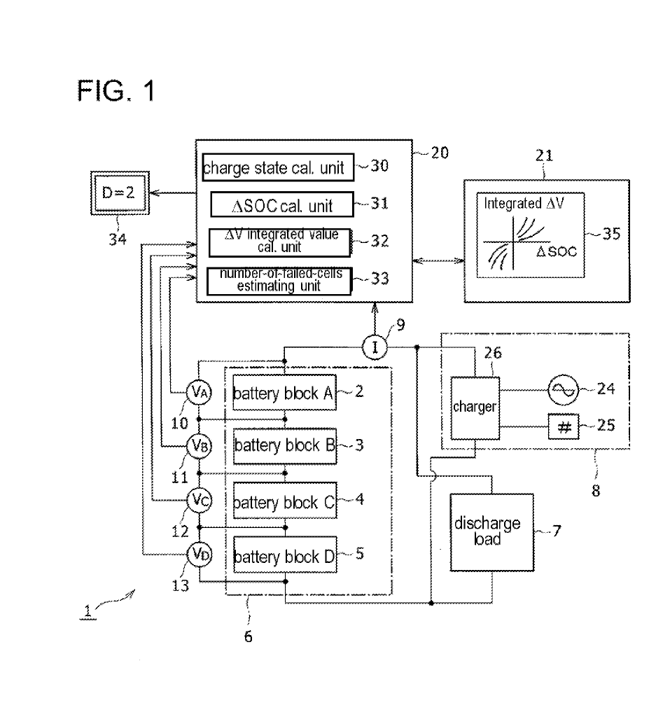

FIG. 1 is a block diagram of failure estimating system 1 for the battery module. Failure estimating system 1 for the battery module includes: battery module 6 formed by interconnecting four battery blocks 2, 3, 4, and 5 in series; current detecting unit 9 for detecting the current output from or input to battery module 6 when battery module 6 is connected to discharge load 7 or charge power source 8; four voltage detecting units 10, 11, 12, and 13 for detecting the inter-terminal voltages of four battery blocks 2 to 5, respectively; failure estimating device 20; and storage unit 21 connected to failure estimating device 20.

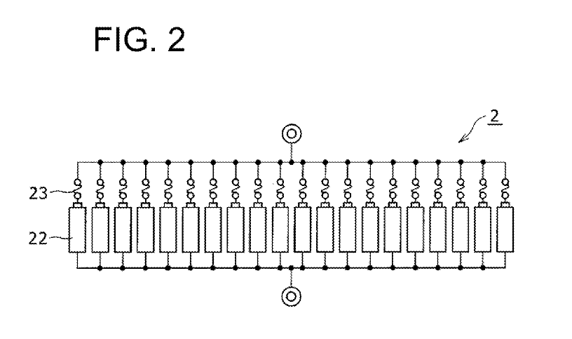

FIG. 2 is a block diagram of battery block 2. Battery block 2 is formed by interconnecting 20 cells 22 in parallel. Each cell 22 is connected in series to element 23 for protecting the cell. Element 23 for protecting the cell is a fuse for protecting the cell from overcurrent, for example. The other battery blocks 3, 4, and 5 have the same configuration.

Each cell 22 is a chargeable/dischargeable secondary cell. As the secondary cell, a lithium-ion cell is used. Instead of this, a nickel-metal-hydride cell or an alkaline cell may be used. Each cell 22 has a cylindrical outer shape. One of both ends of the cylindrical shape is used as a positive terminal, and the other is used as a negative terminal. An example of each cell 22 includes a lithium-ion cell in which the diameter is 18 mm, the height is 65 mm, the inter-terminal voltage is 3.0 to 4.2 V, and the capacity is 2.9 Ah. These numerical values are examples for description, and other dimensions and characteristic values may be used. Each cell is not limited to a cylindrical cell, and may be a cell having another outer shape.

In each of battery blocks 2 to 5, cells 22 are stored in an appropriate case so as to be easily handled. In battery block 2 as an example, 20 cells 22 are interconnected in parallel, so that the capacity is (20×2.9 Ah)=58 Ah. Battery module 6 is formed by storing four battery blocks 2 to 5 in an appropriate case. In battery module 6, the inter-terminal voltage is (3.0 to 4.2 V)×4=(12.0 to 16.8 V).

Discharge load 7 is an apparatus utilizing the discharge power supplied from battery module 6. In this case, a rotary electric machine or electric instrument mounted in a vehicle is employed. As the discharge load, in addition, a household lamp, an electric instrument such as a personal computer, or a luminaire or electric instrument in a factory may be employed.

Charge power source 8 is a power generating device such as commercial power source 24 or solar battery 25, and is connected to battery module 6 via charger 26.

Current detecting unit 9 is a current detecting means for distinctly detecting the charge current that is input from charge power source 8 to battery module 6 and the discharge current that is output from battery module 6 to discharge load 7. As current detecting unit 9, an appropriate ammeter can be employed. The current value detected by current detecting unit 9 is transmitted to failure estimating device 20 through an appropriate signal line. Here, a positive current value is a charge current value, and a negative current value is a discharge current value.

Voltage detecting units 10 to 13 are voltage detecting means for detecting inter-terminal voltages V_{A}, V_{B}, V_{C}, and V_{D} of four battery blocks 2 to 5, respectively. As voltage detecting units 10 to 13, appropriate voltmeters can be employed. Inter-terminal voltages V_{A}, V_{B}, V_{C}, and V_{D} detected by voltage detecting units 10 to 13 are transmitted to failure estimating device 20 through an appropriate signal line.

Failure estimating device 20 estimates and outputs the number of failed cells that do not contribute to charge and discharge, of the plurality of cells 22 constituting each of battery blocks 2 to 5, on the basis of the transmitted detected value of current detecting unit 9 and detected values of voltage detecting units 10 to 13. Failure estimating device 20 can be formed of an appropriate computer.

A failed cell that does not contribute to charge and discharge is a cell that is in an insulated state having no conduction between the positive electrode and negative electrode. In FIG. 2, cell 22 has element 23 for protecting the cell. When element 23 is molten, cell 22 is a failed cell because there is no conduction between the positive electrode and negative electrode. Cell 22 includes a current blocking mechanism. When the gas pressure inside the cell becomes excessive, the current blocking mechanism starts up, and separates the positive electrode from the positive electrode plate in the cell and separates the negative electrode from the negative electrode plate in the cell. Cell 22 in which the current blocking mechanism has started up is a failed cell.

Failure estimating device 20 includes the following components:

charge state calculating unit 30 for calculating the charge state of the battery module by integrating the current detected by current detecting unit 9;

ΔSOC calculating unit 31 that, at each predetermined detection cycle between the initial time and final time of a predetermined failure estimation period, calculates charge state variation ΔSOC—the amount of variation of the charge state from the initial charge state of the battery module—on the basis of the calculated value by charge state calculating unit 30;

ΔV integrated value calculating unit 32 for calculating inter-block maximum voltage difference ΔV—the difference between a maximum inter-terminal voltage value and a minimum inter-terminal voltage value among four battery blocks 2 to 5—at each detection cycle on the basis of the detected values of voltage detecting units 10 to 13, and calculating a ΔV integrated value, which is the integrated value at the final time, by sequentially integrating the calculated ΔV from the initial time of the failure estimation period; and

number-of-failed-cells estimating unit 33 for estimating the number of failed cells.

These functions can be achieved when failure estimating device 20 executes software. Specifically, the functions can be achieved when failure estimating device 20 executes a failure estimation program. A part of the functions may be achieved by hardware.

Output unit 34 connected to failure estimating device 20 is a device for outputting number D of failed cells estimated by number-of-failed-cells estimating unit 33. As output unit 34, an appropriate display can be used. FIG. 1 shows D=2 in output unit 34, and indicates that number D of failed cells is two. Output unit 34 can be disposed separately from failure estimating device 20, and can be configured to communicate with failure estimating device 20 by radio communication or the like. When output unit 34 is disposed separately from failure estimating device 20, a plurality of failure estimating systems for battery modules can be managed collectively by an electronic control unit (ECU).

Storage unit 21 connected to failure estimating device 20 is a memory for storing a program or the like used by failure estimating device 20. Specifically, storage unit 21 stores, as association file 35, the relationship between the ΔSOC and the ΔV integrated value in association with the number of failed cells. Number-of-failed-cells estimating unit 33 of failure estimating device 20 reads, with reference to association file 35, the number of failed cells corresponding to the ΔSOC value calculated by ΔSOC calculating unit 31 and the ΔV integrated value calculated by ΔV integrated value calculating unit 32, and estimates that the read value is the number of failed cells.

In the above description, output unit 34 and storage unit 21 are independent of failure estimating device 20. However, they may be included in failure estimating device 20.

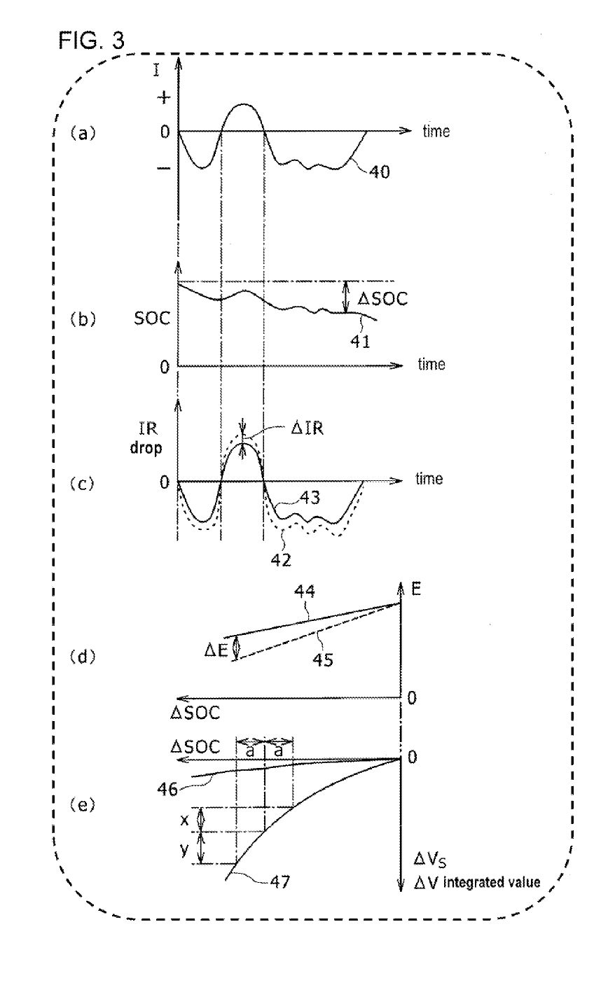

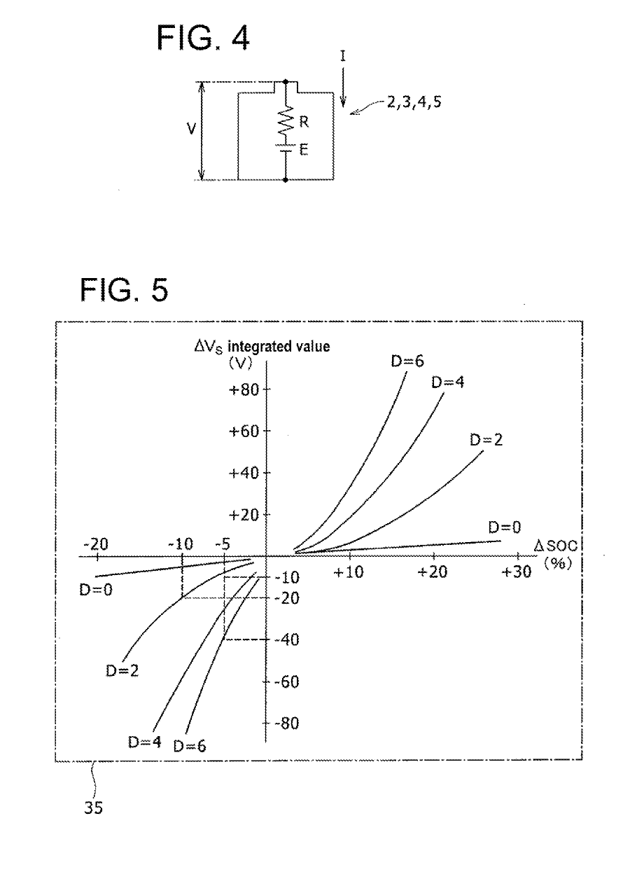

Prior to the description of the contents of association file 35, a principle of associating the relationship between the ΔSOC and ΔV integrated value with the number of failed cells is described using FIG. 3 and FIG. 4. In FIG. 3(a), FIG. 3(b), and FIG. 3(c), all of the horizontal axes show time, and the vertical axes show the charge/discharge current value, and the SOC value and IR drop value indicating the charge/discharge states, respectively. In FIG. 3(d) and FIG. 3(e), both of the horizontal axes show ΔSOC value, and the vertical axes show electromotive force E, and ΔV_{S} and ΔV integrated value, respectively.

In FIG. 3(a), the horizontal axis shows time, and the vertical axis shows the time variation of charge/discharge current value 40 detected by current detecting unit 9. Almost all of charge/discharge current value 40 in the time range shown in FIG. 3(a) is a discharge current value.

FIG. 3(b) shows the time variation of SOC 41. SOC 41 is the value of the charge/discharge state of each of battery blocks 2 to 5 when charge/discharge current value 40 shown in FIG. 3(a) flows through battery module 6. Since almost all of charge/discharge current value 40 in the time range shown in FIG. 3(a) is a discharge current value, the SOC reduces with time. When the reduction amount from the initial SOC is set as ΔSOC, the sign of the ΔSOC when battery module 6 is in the discharge state is opposite to that in the charge state. In other words, the ΔSOC has a negative sign when battery module 6 is in the discharge state greater than the initial SOC, and has a positive sign when battery module 6 is in the charge state greater than the initial SOC.

FIG. 3(c) shows the time variation of the IR drop of each of battery blocks 2 to 5 when charge/discharge current value 40 shown in FIG. 3(a) flows through battery module 6. The IR drops of battery blocks 2 to 5 are different from each other depending on whether or not each battery block includes a failed cell among the plurality of cells 22 constituting it. FIG. 3(c) takes, as an example, the case where battery block 2 includes two failed cells and battery blocks 3 to 5 do not any failed cell at all. FIG. 3(c) shows the time variation of IR drop IR_{A} 42 of battery block 2 and the time variation of IR drop IR_{B} 43 of battery block 3.

As shown in FIG. 3(c), the value (time variation) of IR drop IR_{A} 42 of battery block 2 having two failed cells is larger than the value (time variation) of IR drop IR_{B} 43 of battery block 3 having no failed cell when charge/discharge current value 40 is positive, and is smaller than the value of IR drop IR_{B} 43 when charge/discharge current value 40 is negative.

The reason for this behavior is described using the model of FIG. 4. FIG. 4 is an equivalent model to battery blocks 2, 3, 4, and 5. Battery blocks 2, 3, 4, and 5 can be modeled using internal resistance R_{B} and electromotive force E. When the inter-terminal voltage is set at V and current I in the charge direction is set positive, the expression of inter-terminal voltage V=electromotive force E+current I×internal resistance R is satisfied. At this time, inter-terminal voltage V_{B} of battery block 3 having no failed cell is expressed by inter-terminal voltage V_{B}=electromotive force E_{B}+current I×internal resistance R_{B}. Inter-terminal voltage V_{A} of battery block 2 having two failed cells is expressed by inter-terminal voltage V_{A}=electromotive force E_{A}+current I×internal resistance R_{A}.

In this case, when the internal resistance of each cell 22 is denoted with r, internal resistance R_{B} of battery block 3 having no failed cell satisfies (1/R_{B})=(1/r)×20. While, internal resistance R_{B} of battery block 2 having two failed cells satisfies (1/R_{A})=(1/r)×18. Therefore, internal resistance R_{A} of battery block 2 having two failed cells is (20/18) times larger than internal resistance R_{B} of battery block 3 having no failed cell.

Battery blocks 2 to 5 are interconnected in series, so that charge/discharge current value 40 flowing through battery blocks 2 to 5 is constant. Therefore, the IR drop values of battery blocks 2 and 3 are different from each other depending on the difference in internal resistance R. In this case, the amount of variation of IR drop IR_{A} of battery block 2 is (20/18) times that of IR drop IR_{B} of battery block 3 in the period in which charge/discharge current flows. This is the reason why, in FIG. 3(c), IR drop IR_{A} of battery block 2 is larger than IR drop IR_{B} when charge/discharge current value 40 is positive, and is smaller than IR drop IR_{B} when charge/discharge current value 40 is negative.

As shown in FIG. 3(d), when charge/discharge current value 40 flowing through battery module 6 is in the charge/discharge state shown in FIG. 3(b), electromotive force E_{A} 45 of battery block 2 having two failed cells is smaller than electromotive force E_{B} 44 of battery block 3 having no failed cell. Therefore, as the absolute value of the ΔSOC increases, the difference ΔE between electromotive force E_{B} 44 and electromotive force E_{A} 45 increases.

The reason for this behavior can be described as below. The capacity of battery block 3 having no failed cell is (20×2.9 Ah)=58 Ah. While, the capacity of battery block 2 having two failed cells is (18×2.9 Ah)=52.2 Ah, and is smaller by 5.8 Ah than the former capacity. Since battery blocks 2 to 5 are interconnected in series, charge/discharge current value 40 flowing through battery blocks 2 to 5 is constant. Therefore, the quantity of electricity in battery block 2 having the smaller capacity becomes null earlier than that in battery block 3 having the larger capacity. It is known that there is a correlation between the SOC and electromotive force E. When the discharge progresses, electromotive force E_{A} 45 of battery block 2 having two failed cells decreases earlier than electromotive force E_{B} 44 of battery block 3 having no failed cell. This is the reason why, as the absolute value of the ΔSOC increases, the difference ΔE between electromotive force E_{B} 44 and electromotive force E_{A} 45 increases.

According to FIG. 3(c), there is a possibility that the existence of a failed cell, more specifically the number of failed cells, can be determined on the basis of the magnitude of difference ΔIR between IR drop IR_{A} of battery block 2 and IR drop IR_{B} of battery block 3. In the above-mentioned example, however, ΔIR is as small as about 0.03 V even when discharge is performed at 100 A. In consideration of variation among 20 cells 22 or a measurement error, it is substantially difficult to determine, solely using the ΔIR, the existence of a failed cell, more specifically the number of failed cells. Therefore, when the ΔV expressed by |ΔIR+ΔE|=|V_{B}−V_{A}|=ΔV is integrated in a predetermined discharge period, the difference between battery block 3 having no failed cell and battery block 2 having two failed cells is considered to be clearer than in the case using ΔV. This process is described with reference to FIG. 3(e).

When ΔV is integrated, a positive sign is added to the ΔV in the charge state, and a negative sign is added to the ΔV in the discharge state. The reason for this operation is as follows. When a ΔV integrated value is calculated in the state where a sign is not added to the ΔV, and the charge and discharge are repeated at a similar frequency, the ΔV integrated value monotonically increases though the ΔSOC varies little.

In FIG. 3(e), the horizontal axis shows ΔSOC, and the vertical axis shows ΔV_{S} 46, and ΔV integrated value 47 obtained by integrating ΔV_{S}. Here, ΔV_{S} 46 is obtained by adding the positive sign to the ΔV in the charge state, or adding the negative sign to the ΔV in the discharge state. Furthermore, ΔV integrated value 47 of FIG. 3(e) increases quadratically as the absolute value of the ΔSOC increases. Therefore, the existence of a failed cell, more specifically the number of failed cells, can be determined using ΔV integrated value 47.

FIG. 5 is a diagram showing an example of association file 35 that associates the relationship between the ΔSOC and ΔV integrated value with the number of failed cells. FIG. 5 shows the result of the following processes:

an in-vehicle battery module is formed by interconnecting, in series, battery blocks 2 (described in FIG. 2) as many as the number suitable for mounting in the vehicle; and

the ΔSOC and the ΔV integrated value are determined by actually applying the in-vehicle battery module to the power running and regeneration of a vehicle, as described in FIG. 3.

During the power running of the vehicle, the in-vehicle battery module is in the discharge state. During the regeneration of the vehicle, the in-vehicle battery module is in the charge state. In this case, number D of failed cells is set at 0, 2, 4, or 6.

The horizontal axis of FIG. 5 shows ΔSOC. As discussed in FIG. 3(b), the ΔSOC has a positive sign when the in-vehicle battery module is in the charge state, and has a negative sign when the in-vehicle battery module is in the discharge state. The vertical axis of FIG. 5 shows ΔV integrated value. As discussed in FIG. 3(d), ΔV_{S} as the absolute value of the ΔV having a sign is used for calculating the ΔV integrated value. In FIG. 5, D denotes the number of failed cells.

As shown in FIG. 5, as number D of failed cells increases, the absolute value of the ΔV integrated value increases. By applying the calculated ΔSOC and ΔV integrated value to association file 35, number D of failed cells can be determined. For example, when ΔSOC=−10% and ΔV integrated value=−20 V are calculated, number D of failed cells is 2.

Association file 35 of FIG. 5 can be previously determined by an experiment or the like using determined battery module 6. Previously determined association file 35 is stored in storage unit 21.

In FIG. 5, association file 35 is described as a map. The pattern of association file 35 may be a pattern other than a map as long as the ΔSOC, the ΔV integrated value, and number D of failed cells are associated with each other. For example, a pattern such as a look-up table, an equation, or a read only memory (ROM) that, upon receiving two of the ΔSOC, the ΔV integrated value, and number D of failed cells, outputs remaining one parameter may be employed.

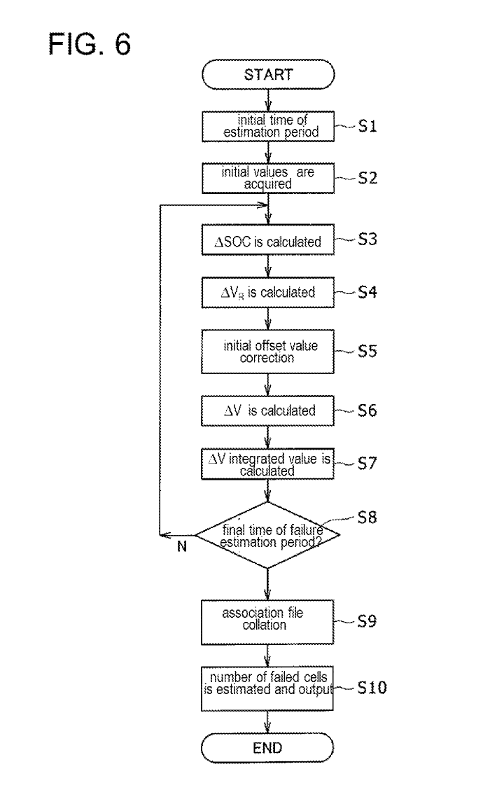

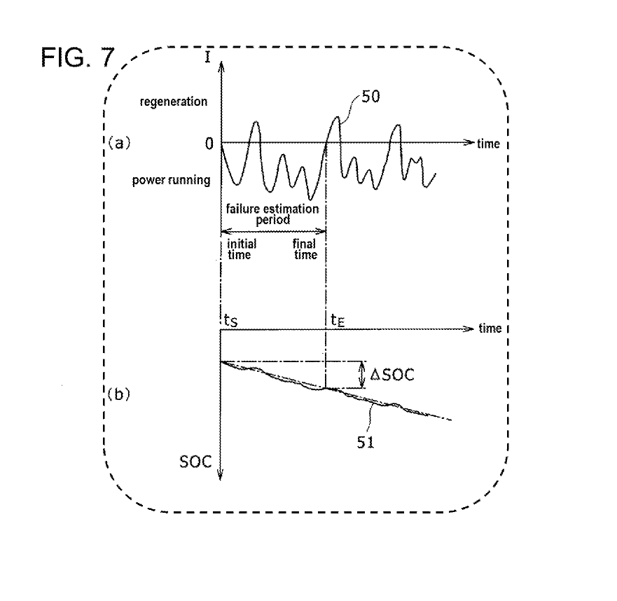

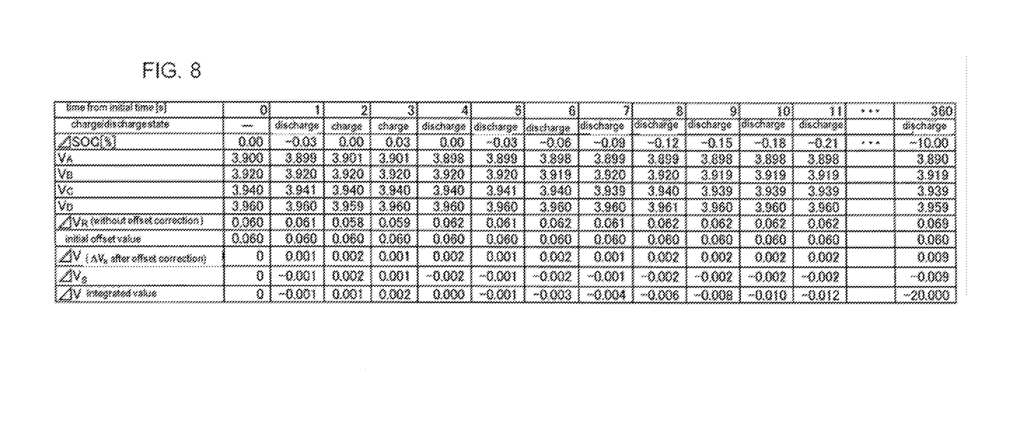

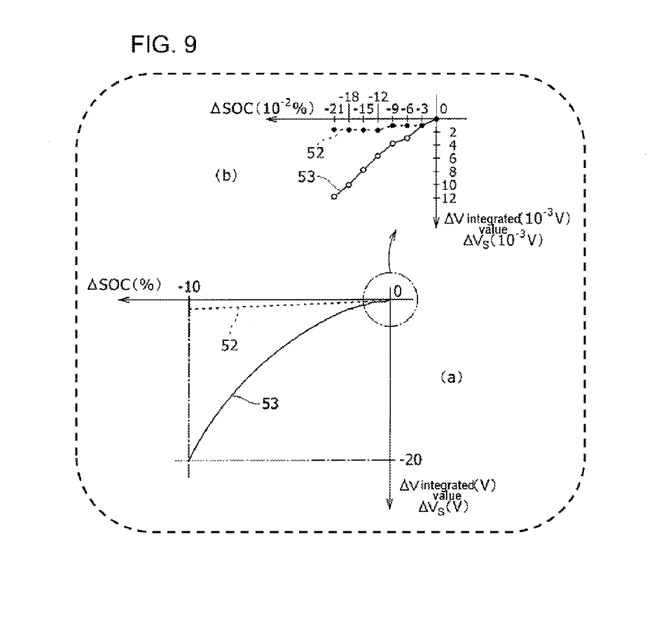

The operation of the above-mentioned configuration is described in more detail using FIG. 6 to FIG. 9. Hereinafter, a procedure of estimating number D of failed cells in battery module 6 that is constituted by four battery blocks 2 to 5 shown in FIG. 1 is described. FIG. 6 is a flowchart showing the procedure of failure estimation of battery module 6. FIG. 7 is a diagram illustrating a failure estimation period. FIG. 8 is a diagram showing the process of calculating an actual ΔV integrated value. FIG. 9 is a diagram illustrating the process of estimating number D of failed cells on the basis of the result in FIG. 8.

The failure estimation is performed in a predetermined failure estimation period. FIG. 7 is a diagram showing the failure estimation period. FIG. 7(a) is a diagram showing the time variation of charge/discharge current value 50 in battery module 6, and corresponds to FIG. 3(a). This drawing shows the time variation of charge/discharge current value 50 when an in-vehicle rotary electric machine as a discharge load of battery module 6 is in the power running state or sometimes comes into the regeneration state. FIG. 7(b) is a diagram showing the time variation of SOC 51 corresponding to FIG. 7(a).

The failure estimation period is the period between time is as the initial time and time t_{E} as the final time. The failure estimation period can be set as a predetermined time period. For example, the failure estimation period can be set as 10 min from the initial time. Alternatively, the failure estimation period can be set on the basis of the value of the ΔSOC in the period from the initial time to the final time, and, for example, can be set as the period from the initial time to the arrival time of the ΔSOC at 10%. In this case, the failure estimation period is set to be the period from the initial time to the arrival time of the ΔSOC at 10%.

In FIG. 6, when the failure estimation period is set, at the initial time thereof (S1), initial values required for failure estimation are acquired (S2). The acquired initial values are the initial value of the SOC and the initial values of inter-terminal voltages V_{A}, V_{B}, V_{C}, and V_{D} of battery blocks 2 to 5.

The initial value of the SOC is acquired by the following processes:

the current detected by current detecting unit 9 is integrated with respect to time:

the ratio (%) of the quantity of electricity (current value×time) to the capacity (58 Ah) of battery module 6 is calculated; and

the ratio is set as the SOC, which is a value showing the charge state of battery module 6.

This processing procedure is executed by the function of charge state calculating unit 30 of failure estimating device 20.

When the initial values at the initial time are acquired, the ΔSOC is calculated (S3) and ΔV_{R} is calculated (S4) at a predetermined detection cycle from the initial time.

The ΔSOC is calculated as the amount of time variation of the SOC on the basis of the SOC that is momentarily calculated by charge state calculating unit 30, as described in FIG. 3(c). The calculation procedure of the ΔSOC is executed by the function of ΔSOC calculating unit 31 of failure estimating device 20.

In FIG. 8, the horizontal axis shows time from the initial time, and the vertical axis shows the charge/discharge state, ΔSOC, and inter-terminal voltages V_{A}, V_{B}, V_{C}, and V_{D}. FIG. 8 shows the process of calculating the ΔV integrated value on the basis of the time variation of the ΔSOC, V_{A}, V_{B}, V_{C}, and V_{D}. In FIG. 8, the detection cycle is set at 1 s, and the time at which the ΔSOC becomes −10% is set at 360 s. The time variation of the charge/discharge state, ΔSOC, V_{A}, V_{B}, V_{C}, and V_{D} from the initial time to 11 s is shown, and the values of the V_{A}, V_{B}, V_{C}, and V_{D} at the final time when the ΔSOC is −10% are shown. Here, time variation after 11 s and before the final time is omitted. The values of V_{A}, V_{B}, V_{C}, and V_{D} described later are examples for description, and the other values may be used.

In FIG. 8, the initial values are V_{A}=3.900 V, V_{B}=3.920 V, V_{C}=3.940 V, and V_{D}=3.960 V. Here, ΔV_{R} is calculated as the difference between the maximum value and the minimum value among four inter-terminal voltages V_{A}, V_{B}, V_{C}, and V_{D}. In this case, the maximum inter-terminal voltage value is V_{D}=3.960 V and the minimum inter-terminal voltage value is V_{A}=3.900 V, so that the ΔV_{R} is calculated as ΔV_{R}=0.060 V. FIG. 8 shows the ΔV_{R} that is calculated at each time elapsed from the initial time on the basis of the maximum inter-terminal voltage value and the minimum inter-terminal voltage value among the V_{A}, V_{B}, V_{C}, and V_{D}. For example, at the final time of the failure estimation period, ΔV_{R}=0.069 V is calculated.

The description returns to FIG. 6. When the ΔV_{R} is calculated, the ΔV_{R} is corrected using an initial offset value (S5) to provide ΔV (S6). The initial offset value is the value of ΔV_{R} at the initial time of the failure estimation period. In the example of FIG. 8, the initial offset value is 0.060 V. The initial offset value indicates the variation among four battery blocks 2 to 5, so that the variation is applied to the correction of ΔV_{R} and the value after the correction is set at ΔV.

In FIG. 8, ΔV_{R} is 0.060 V and initial offset value is 0.060 V at the initial time, so that ΔV=|ΔV_{R}−(initial offset value)|=|0.060 V−0.060 V|=0 V is satisfied. The expression of ΔV_{R}=0.061 V is satisfied after 1 s from the initial time, so that ΔV=|ΔV_{R}−(initial offset value)|=|0.061 V−0.060 V|=0.001 V is satisfied. Similarly, ΔV_{R} is 0.058 V after 2 s from the initial time, so that ΔV=|ΔV_{R}−(initial offset value)|=|0.058 V−0.060 V|=0.002 V is satisfied.

The description returns to FIG. 6 again. When the ΔV is calculated, the ΔV_{S} is determined by adding a sign to the ΔV depending on the charge/discharge state, and the ΔV integrated value is calculated by integrating ΔV_{S} (S7). This processing procedure is executed by the function of ΔV integrated value calculating unit 32 of failure estimating device 20. The ΔV integrated value is calculated by sequentially integrating the ΔV_{S} from the initial time of the failure estimation period.

In FIG. 8, ΔV is 0.001 V after 1 s from the initial time. The charge/discharge state indicates discharge, so that ΔV_{S}=−0.001 V is obtained by adding the negative sign to ΔV. Therefore, after a lapse of 1 s from the initial time, ΔV integrated value=0 V−0.001 V=−0.001 V is satisfied. Similarly, ΔV is 0.002 V and the charge/discharge state indicates charge after 2 s from the initial time, so that ΔV_{S}=0.002 V is obtained by adding the positive sign. Therefore, after a lapse of 2 s from the initial time, ΔV integrated value=−0.001 V+0.002 V=0.001 V is satisfied. As shown in FIG. 8, the ΔV integrated value is calculated by adding a sign to the ΔV calculated at each detection cycle and sequentially integrating the ΔV from the initial time of the failure estimation period. For example, after a lapse of 11 s from the initial time, ΔV integrated value=−0.012 V is calculated.

The description returns to FIG. 6 again. It is determined whether it is the final time of the failure estimation period (S8). When the determination result is NO in S8, the process returns to S3 and the above-mentioned procedure is repeated. When the determination result is YES in S8, it is the final time of the failure estimation period. Therefore, the ΔSOC and ΔV integrated value at this time are collated with association file 35 (S9), number D of failed cells is estimated, and the estimation result is output to output unit 34 (S10). This processing procedure is executed by the function of number-of-failed-cells estimating unit 33 of failure estimating device 20.

In FIG. 8, the ΔSOC becomes −10% at the final time of the failure estimation period. The final time corresponds to 360 s after the initial time. At the final time, ΔV integrated value is −20 V.

In FIG. 9, the horizontal axis shows ΔSOC, and the vertical axis shows ΔV_{S} and ΔV integrated value. FIG. 9 shows the results calculated with time in FIG. 8. FIG. 9(a) shows the overall range, and FIG. 9(b) enlarges and shows the range where the ΔSOC is from 0 to −0.21%. The state of ΔSOC=0.21% corresponds to the time after a lapse of 11 s from the initial time in FIG. 8. FIG. 9(a) and FIG. 9(b) show the time variation of ΔV_{S} 52 and the time variation of ΔV integrated value 53. The value of ΔV_{S} 52 gently increases with time correspondingly to the variation of ΔSOC. Therefore, ΔV integrated value 53 steeply increases with time as the ΔSOC increases. Thus, in order to estimate the existence of a failed cell and number D of failed cells, use of the ΔV integrated value is more preferable than use of ΔV_{S}.

When FIG. 9 (a) is collated with association file 35 of FIG. 5, ΔSOC=−10% and ΔV integrated value=−20 V correspond to number D of failed cells=2. Thus, by calculating the ΔSOC and ΔV integrated value in battery module 6 and collating the calculation result with association file 35, number D of failed cells included in battery module 6 can be estimated.

In the present exemplary embodiment, ΔV_{R} is calculated from the maximum inter-terminal voltage value and minimum inter-terminal voltage value among the V_{A}, V_{B}, V_{C}, and V_{D}. However, ΔV_{R} can be calculated by comparing the average value of the V_{A}, V_{B}, V_{C}, and V_{D} with each of the V_{A}, V_{B}, V_{C}, and V_{D}. In this case, ΔV_{R} can be calculated for each of the V_{A}, V_{B}, V_{C}, and V_{D}. By calculating ΔV_{R} for each of the V_{A}, V_{B}, V_{C}, and V_{D}, it can be determined which of battery blocks 2 to 5 has a failed cell, and number D of failed cells can be estimated.

In the present exemplary embodiment, the failure estimation is performed after the failure estimation period is previously determined. However, the failure estimation can be performed without previously determining the failure estimation period. The failure estimation is described below.

When the failure estimation is started, an initial value required for the failure estimation is acquired at the initial time (corresponding to S2). When the initial value at the initial time is acquired, the ΔSOC is calculated (corresponding to S3) and ΔV_{R} is calculated (corresponding to S4) at a predetermined detection cycle from the initial time. When the ΔV_{R} is calculated, the ΔV_{R} is corrected using an initial offset value (corresponding to S5) to provide ΔV (corresponding to S6). Next, the ΔV_{S} is determined by adding a sign to the ΔV depending on the charge/discharge state, and the ΔV integrated value is calculated by integrating the ΔV_{S} (corresponding to S7). By collating the ΔSOC at this time and the calculated ΔV integrated value with association file 35, number D of failed cells is estimated.

For example, when the ΔSOC is −5%, the following states can be detected with reference to association file 35. When the ΔV integrated value is −10 V or lower, two or more cells are failed. When the ΔV integrated value is −20 V or lower, four or more cells are failed. When the ΔV integrated value is −40 V or lower, six or more cells are failed.

Therefore, number D of failed cells can be estimated without determining the failure estimation period, and the estimation result can be output to output unit 34. This processing procedure is executed by the function of number-of-failed-cells estimating unit 33 of failure estimating device 20.

In the present exemplary embodiment, the existence of a failed cell is determined by referring to association file 35. However, the existence of a failed cell can be determined also on the basis of ΔV integrated value 47 of FIG. 3(e). Here, ΔV integrated value 47 can be calculated when a failed cell exists, and ΔV integrated value 47 of FIG. 3(e) increases quadratically as the absolute value of the ΔSOC increases. In other words, variation rates x and y of ΔV integrated value 47 satisfy the expression of y>x though the variation width a of the ΔSOC is constant. Thus, the existence of a failed cell can be determined also by using the variation of the variation rates of ΔV integrated value 47.

### REFERENCE MARKS IN THE DRAWINGS

1 failure estimating system for battery module
2, 3, 4, 5 battery block
6 battery module
7 discharge load
8 charge power source
9 current detecting unit
10, 11, 12, 13 voltage detecting unit
20 failure estimating device
21 storage unit
22 cell
23 element (for cell protection)
24 commercial power source
25 solar battery
26 charger
30 charge state calculating unit
31 ΔSOC calculating unit
32 ΔV integrated value calculating unit
33 number-of-failed-cells estimating unit
34 output unit
35 association file
40, 50 charge/discharge current value
41, 51 SOC
42, 43 IR drop
44, 45 electromotive force E
46, 52 V_{S}
47, 53 ΔV integrated value

1. A failure estimating system for a battery module comprising:
a battery module formed by interconnecting a plurality of battery blocks in series, each of the plurality of battery blocks including a plurality of cells interconnected in parallel;
a current detecting unit for detecting a current output from or input to the battery module when the battery module is connected to a discharge load or a charge power source;
a plurality of voltage detecting units for detecting an inter-terminal voltage of each of the plurality of battery blocks; and
a failure estimating device for estimating and outputting a number of failed cells that do not contribute to charge and discharge, of the plurality of cells constituting each of the plurality of battery blocks,
wherein the failure estimating device includes:
a charge state calculating unit for calculating a charge state of the battery module by integrating the current detected by the current detecting unit;
a ΔSOC calculating unit for calculating ΔSOC as a charge state variation based on a calculated value by the charge state calculating unit at each of predetermined detection cycles between an initial time and a final time of a predetermined failure estimation period, the charge state variation being an amount of variation of the charge state from a charge state of the battery module at the initial time;
a ΔV integrated value calculating unit for calculating ΔV as an inter-block maximum voltage difference at each of the detection cycles based on detected values by the voltage detecting units, and calculating a ΔV integrated value by sequentially integrating the calculated ΔV from the initial time of the failure estimation period, the ΔV integrated value being an integrated value at the final time, the inter-block maximum voltage difference being a difference between a maximum inter-terminal voltage value and a minimum inter-terminal voltage value among the plurality of battery blocks;
a storage unit for storing, as an association file, a relationship between the ΔSOC and the ΔV integrated value in association with the number of failed cells; and
an estimating unit for estimating the number of failed cells with reference to the association file, the number of failed cells corresponding to the ΔSOC and the ΔV integrated value at the final time of the failure estimation period.

2. The failure estimating system for the battery module according to claim 1, wherein
the ΔSOC calculating unit sets a sign of the ΔSOC so that the sign when the battery module is in a charge state is opposite to the sign when the battery module is in a discharge state, and
the ΔV integrated value calculating unit integrates the ΔV after adding a sign to the ΔV so that the sign when the battery module is in the charge state is different from the sign when the battery module is in the discharge state.

3. The failure estimating system for the battery module according to claim 1, wherein
the ΔV integrated value calculating unit sets, as an initial offset value, the ΔV at the initial time of the failure estimation period, and corrects the initial offset value based on the ΔV calculated at each of the detection cycles.

4. The failure estimating system for the battery module according to claim 1, wherein
in the association file, each of the failed cells is set as a cell that is in an insulated state having no conduction between a positive electrode and a negative electrode.
